(19) United States
(12) Patent Application Publication
(10) Pub. No.: US 2021/0235548 A1
(43) Pub. Date: Jul. 29, 2021

(54) CERAMIC HEATER

(71) Applicant: NGK INSULATORS, LTD., Nagoya-City (JP)

(72) Inventors: Masaki ISHIKAWA, Handa-City (JP); Shuichiro MOTOYAMA, Nagoya-City (JP)

(73) Assignee: NGK INSULATORS, LTD., Nagoya-City (JP)

(21) Appl. No.: 17/301,773

(22) Filed: Apr. 14, 2021

Related U.S. Application Data
(63) Continuation of application No. PCT/JP2019/050764, filed on Dec. 25, 2019.

(30) Foreign Application Priority Data
Jan. 25, 2019 (JP) 2019-011300

(51) Int. Cl. H05B 3/28; H05B 3/18; H05B 3/14

(52) U.S. Cl. CPC H05B 3/283; H01L 21/67103; H05B 3/14; H05B 3/18

(57) ABSTRACT

A ceramic heater includes a ceramic plate, a main resistance heating element, and a sub resistance heating element. The main resistance heating element is a coil that is disposed in the ceramic plate, that is wired from one of a pair of main terminals in a one-stroke pattern, and that reaches the other of the pair of the main terminals. The sub resistance heating element is a heating element that is disposed in the ceramic plate, that complements heating with the main resistance heating element, and that has a two-dimensional shape.

### BACKGROUND OF THE INVENTION

### 1. Field of the Invention

The present invention relates to a ceramic heater.

### 2. Description of the Related Art

For a semiconductor-manufacturing apparatus, a ceramic heater that heats a wafer is used. A so-called two-zone heater is known as such a ceramic heater. In a heater known as this kind of two-zone heater, as disclosed in PTL 1, an inner-peripheral resistance heating element and an outer-peripheral resistance heating element are embedded in a ceramic base on the same plane, and heat generated from the resistance heating elements is separately controlled by separately applying a voltage to the resistance heating elements. Each resistance heating element is a coil composed of high-melting-point metal such as tungsten.

### CITATION LIST

### Patent Literature

PTL 1: Japanese Patent No. 3897563 B

### SUMMARY OF THE INVENTION

According to PTL 1, however, the resistance heating elements are the coils, and accordingly, the adjacent coils need to be spaced from each other so as not to short-circuit. The ceramic heater has a gas hole and a lift pin hole that extend through a ceramic plate in the vertical direction, and the resistance heating elements need to detour around the holes. For this reason, there is a problem in that sufficient thermal uniformity cannot be achieved.

The present invention has been accomplished to solve the problems, and it is a main object of the present invention to achieve sufficient thermal uniformity even in the case where a coil is used as a main resistance heating element.

A ceramic heater according to the present invention includes

a ceramic plate that has a wafer placement surface;

a main resistance heating element that is disposed parallel with the wafer placement surface in the ceramic plate, that is wired from one of a pair of main terminals in a one-stroke pattern, that reaches the other of the pair of main terminals, and that has a coil shape; and

a sub resistance heating element that is disposed in the ceramic plate, that complements heating with the main resistance heating element, and that has a two-dimensional shape.

In the ceramic heater, the main resistance heating element that is disposed in the ceramic plate and that has a coil shape heats a wafer that is placed on the wafer placement surface. The main resistance heating element is a coil and is accordingly restricted when wired. For this reason, just heating with the main resistance heating element is likely to create a point at which temperature singularly decreases, that is, temperature singularity. According to the present invention, the sub resistance heating element that heats the temperature singularity and that has a two-dimensional shape is disposed in the ceramic plate. The sub resistance heating element has a two-dimensional shape and can be accordingly manufactured by printing, and this achieves wiring with a high degree of freedom (for example, a line distance is decreased for wiring at a high density). For this reason, the sub resistance heating element can complement heating with the main resistance heating element that has a coil shape. Accordingly, sufficient thermal uniformity can be achieved even in the case where the coil is used as the main resistance heating element.

The main resistance heating element and the sub resistance heating element may be composed of the same material or composed of different materials. The word “parallel” includes not only a case of being completely parallel but also a case of being substantially parallel (for example, a case of being within tolerance). The sub resistance heating element may be disposed on the same plane as the main resistance heating element or a different plane therefrom. The word “same” includes not only a case of being completely the same but also a case of being substantially the same (for example, a case of being within tolerance).

In the ceramic heater according to the present invention, the ceramic plate may have a hole that extends therethrough in a vertical direction, and the sub resistance heating element may be disposed around the hole. The main resistance heating element is wired so as to detour around the hole that extends through the ceramic plate in the vertical direction. For this reason, a portion around the hole is likely to have the temperature singularity. The sub resistance heating element is disposed around the hole here, and the portion around the hole can be prevented from having the temperature singularity.

In the ceramic heater according to the present invention, the main resistance heating element may extend from the one of the pair of main terminals, may be folded at folded portions, and may reach the other of the pair of main terminals, and the sub resistance heating element may be disposed at a portion at which the folded portions of the main resistance heating element face each other. There is no main resistance heating element at the portion at which the folded portions of the main resistance heating element face each other, and the portion is likely to have the temperature singularity. The sub resistance heating element is disposed at the portion here, and accordingly, the portion can be prevented from having the temperature singularity.

In the ceramic heater according to the present invention, the sub resistance heating element may be disposed in a space between parts of a wiring line of the main resistance heating element. The space between the parts of the wiring line of the main resistance heating element is relatively wide in view of insulation and is accordingly likely to have the temperature singularity. The sub resistance heating element is disposed in the space here, and accordingly, the space can be prevented from having the temperature singularity.

In the ceramic heater according to the present invention, the sub resistance heating element may form a parallel circuit together with the main resistance heating element. In this case, it is not necessary for the sub resistance heating element to include an exclusive terminal.

In the ceramic heater according to the present invention, the sub resistance heating element may be wired from one of a pair of sub terminals in a one-stroke pattern and reaches the other of the pair of sub terminals. This enables heating with the main resistance heating element and heating with the sub resistance heating element to be separately controlled.

In the ceramic heater according to the present invention, the sub resistance heating element may contain ceramics. With the ceramics contained, the thermal expansion coefficient of the sub resistance heating element can be close to the thermal expansion coefficient of the ceramic plate, and bonding strength between the sub resistance heating element and the ceramic plate can be increased.

In the ceramic heater according to the present invention, the sub resistance heating element may be disposed so as to bridge a curved portion of the main resistance heating element, and a coil winding pitch of the curved portion may be less than a coil winding pitch outside the curved portion. In this case, the coil winding pitch of the curved portion is less than the coil winding pitch outside the curved portion, and accordingly, the amount of heat generation of the curved portion increases. For this reason, the amount of heat generation of the curved portion can be inhibited from decreasing as a result of the curved portion and the sub resistance heating element arranged in parallel.

### BRIEF DESCRIPTION OF THE DRAWINGS

FIG. 1 is a perspective view of a ceramic heater 10.

FIG. 2 is a longitudinal sectional view of the ceramic heater 10.

FIG. 3 is a sectional view of a ceramic plate 20 taken along a plane parallel with resistance heating elements 22 and 24 and viewed from above.

FIG. 4 is a sectional view of a ceramic plate 120 taken along a plane parallel with resistance heating elements 122 and 123 and viewed from above.

FIG. 5 is a sectional view of another example of the ceramic plate 120.

FIG. 6 is a sectional view of a ceramic plate 220 taken along a plane parallel with resistance heating elements 222 and 223 and viewed from above.

FIG. 7 is a sectional view of another example of the ceramic plate 220.

### DETAILED DESCRIPTION OF THE INVENTION

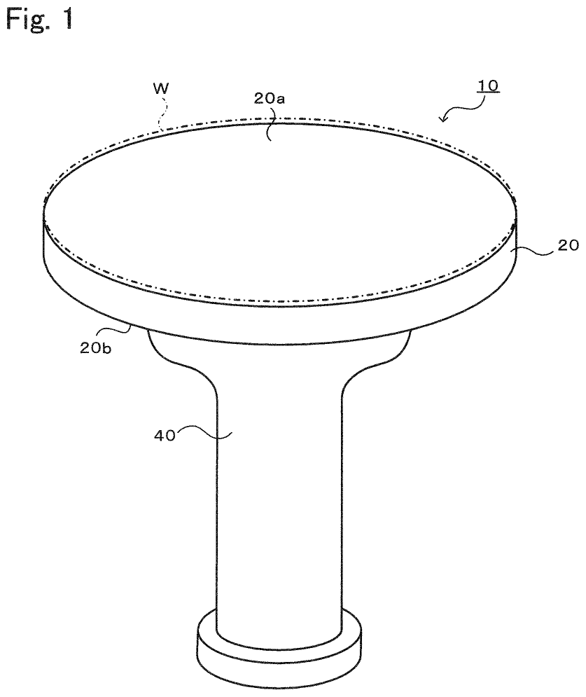

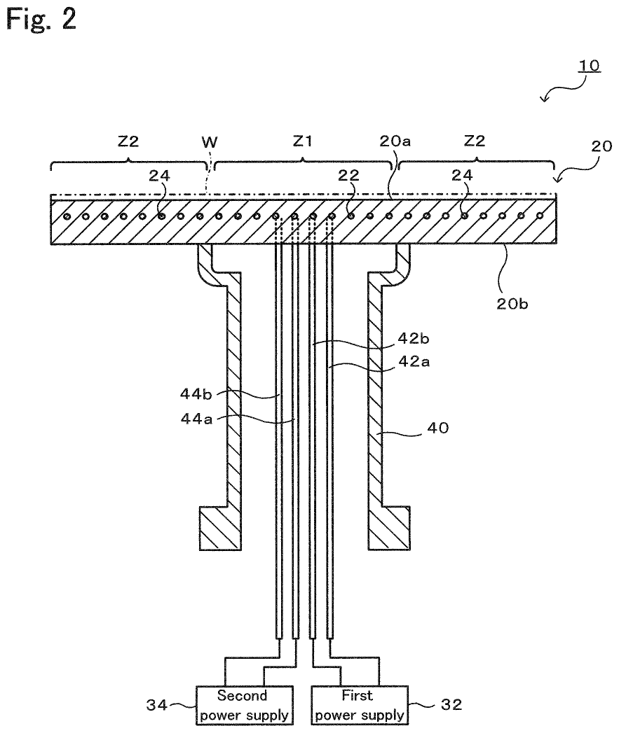

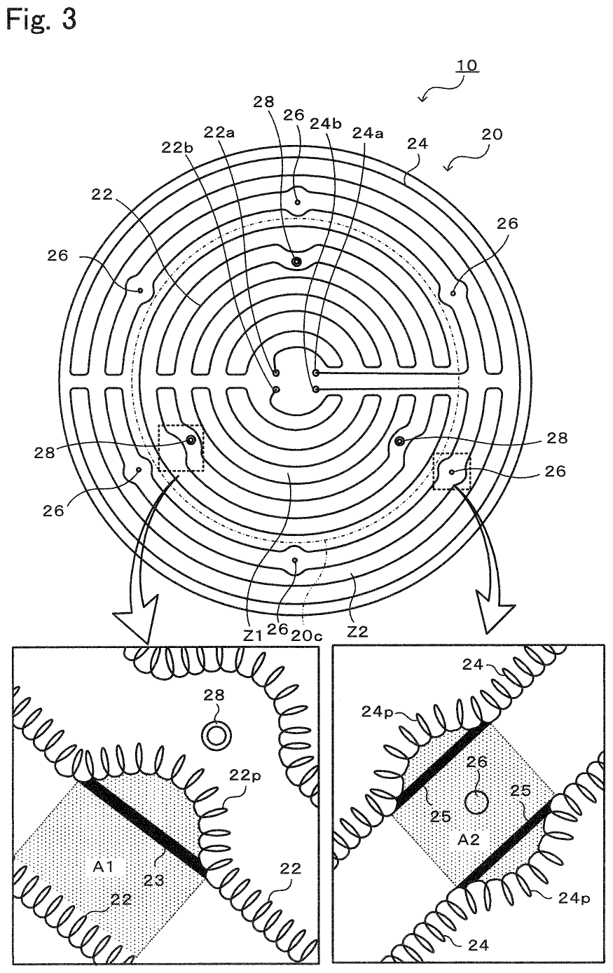

A preferred embodiment of the present invention will hereinafter be described with reference to the drawings. FIG. 1 is a perspective view of a ceramic heater 10 according to a first embodiment. FIG. 2 is a longitudinal sectional view (a sectional view of the ceramic heater 10 taken along a plane containing a central axis) of the ceramic heater 10. FIG. 3 is a sectional view of a ceramic plate 20 taken along a plane parallel with resistance heating elements 22 and 24 and viewed from above. FIG. 3 illustrates the ceramic plate 20 substantially viewed from a wafer placement surface 20a. In FIG. 3, hatching representing a section is omitted.

The ceramic heater 10 is used to heat a wafer that is subjected to a process such as etching or CVD and is installed in a vacuum chamber not illustrated. The ceramic heater 10 includes the ceramic plate 20 that has the wafer placement surface 20a and that is discoid, and a tubular shaft 40 that is joined coaxially with the ceramic plate 20 to a surface (a back surface) 20b of the ceramic plate 20 opposite the wafer placement surface 20a.

The ceramic plate 20 is a discoid plate composed of a ceramic material, representatively, aluminum nitride or alumina. The diameter of the ceramic plate 20 is, for example, about 300 mm. Fine irregularities are formed on the wafer placement surface 20a of the ceramic plate 20 by an embossing process, although these are not illustrated. An imaginary boundary 20c (see FIG. 3) that is concentric with the ceramic plate 20 divides the ceramic plate 20 into an inner-peripheral zone Z1 that has a small circular shape and an outer-peripheral zone Z2 that has an annular shape. The diameter of the imaginary boundary 20c is, for example, about 200 mm. The inner-peripheral main resistance heating element 22 and inner-peripheral sub resistance heating elements 23 are embedded in the inner-peripheral zone Z1 of the ceramic plate 20. The outer-peripheral main resistance heating element 24 and outer-peripheral sub resistance heating elements 25 are embedded in the outer-peripheral zone Z2. The resistance heating elements 22 to 25 are disposed on the same plane parallel with the wafer placement surface 20a.

As illustrated in FIG. 3, the ceramic plate 20 has gas holes 26. The gas holes 26 extend through the ceramic plate 20 from the back surface 20b to the wafer placement surface 20a. Gas is supplied to spaces between the irregularities that are formed on the wafer placement surface 20a and a wafer W that is placed on the wafer placement surface 20a. The gas that is supplied to the spaces improves heat conduction between the wafer placement surface 20a and the wafer W. The ceramic plate 20 also has multiple lift pin holes 28. The lift pin holes 28 extend through the ceramic plate 20 from the back surface 20b to the wafer placement surface 20a, and lift pins, not illustrated, are inserted therein. The lift pins lift the wafer W that is placed on the wafer placement surface 20a. According to the present embodiment, the lift pin holes 28 are concentrically arranged at a regular interval, and the number thereof is three.

As illustrated in FIG. 3, the inner-peripheral main resistance heating element 22 extends from one of a pair of main terminals 22a and 22b disposed on a central portion (a region of the back surface 20b of the ceramic plate 20 that is surrounded by the tubular shaft 40) of the ceramic plate 20, is folded at folded portions in a one-stroke pattern, is wired over the substantially entire inner-peripheral zone Z1, and reaches the other of the pair of the main terminals 22a and 22b. The inner-peripheral main resistance heating element 22 is disposed so as to detour around the lift pin holes 28. The inner-peripheral main resistance heating element 22 is a coil a main component of which is high-melting-point metal or carbide thereof. Examples of the high-melting-point metal include tungsten, molybdenum, tantalum, platinum, rhenium, hafnium, and an alloy thereof. Examples of the carbide of the high-melting-point metal include tungsten carbide and molybdenum carbide. In the inner-peripheral zone Z1, the inner-peripheral sub resistance heating elements 23 are disposed around the lift pin holes 28 in addition to the inner-peripheral main resistance heating element 22 (see in a frame at the lower left in FIG. 3). Around the lift pin holes 28, there are curved portions 22p that approach the lift pin holes 28 in the inner-peripheral main resistance heating element 22. A hatching region A1 that is surrounded by the inner-peripheral main resistance heating element 22 that is located outside the curved portions 22p and the curved portions 22p is wider than the other region and is likely to have temperature singularity. For this reason, the inner-peripheral sub resistance heating elements 23 have a ribbon shape (a flat elongated shape) and are linearly disposed so as to bridge the curved portions 22p. The electric resistance of the inner-peripheral sub resistance heating elements 23 across bridge points is not particularly limited but may be, for example, 10 to 100 times the electric resistance of the inner-peripheral main resistance heating element 22 (that is, the curved portions 22p) across the bridge points. The electric resistance of the inner-peripheral sub resistance heating elements 23 can be adjusted by the material of the inner-peripheral sub resistance heating elements 23, the size of a sectional area, or the lengths of the bridge points. The inner-peripheral sub resistance heating elements 23 form parallel circuits together with the inner-peripheral main resistance heating element 22. The inner-peripheral sub resistance heating elements 23 can be formed by applying high-melting-point metal or the paste of carbide thereof by printing. The frame at the lower left in FIG. 3 contains an enlarged view of a portion around one of the lift pin holes 28. However, the inner-peripheral sub resistance heating elements 23 are formed around the other lift pin holes 28 in the same manner. In the case where a problem arises from a decrease in the amount of heat generation of each curved portion 22p as a result of the curved portion 22p and the inner-peripheral sub resistance heating elements 23 being arranged in parallel, the problem can be solved by decreasing the coil winding pitch of the curved portion 22p to be less than the coil winding pitch outside the curved portion 22p such that the amount of heat generation of the curved portion 22p increases.

As illustrated in FIG. 3, the outer-peripheral main resistance heating element 24 extends from one of a pair of terminals 24a and 24b disposed on the central portion of the ceramic plate 20, is folded at folded portions in a one-stroke pattern, is wired over the substantially entire outer-peripheral zone Z2, and reaches the other of the pair of the terminals 24a and 24b. The outer-peripheral main resistance heating element 24 is disposed so as to detour around the gas holes 26. The outer-peripheral main resistance heating element 24 is a coil a main component of which is high-melting-point metal or carbide thereof. However, sections from the terminals 24a and 24b to the outer-peripheral zone Z2 are formed by a wiring line composed of the high-melting-point metal or carbide thereof. In the outer-peripheral zone Z2, the outer-peripheral sub resistance heating elements 25 are disposed around the gas holes 26 in addition to the outer-peripheral main resistance heating element 24 (see in a frame at the lower right in FIG. 3). Around the gas holes 26, there are curved portions 24p that detour around the gas holes 26 in the outer-peripheral main resistance heating element 24. A hatching region A2 that is surrounded by the two curved portions 24p facing each other is likely to have the temperature singularity. For this reason, the outer-peripheral sub resistance heating elements 25 have a ribbon shape and are linearly disposed so as to bridge the curved portions 24p. The electric resistance of the outer-peripheral sub resistance heating elements 25 across bridge points is not particularly limited but may be, for example, 10 to 100 times the electric resistance of the outer-peripheral main resistance heating element 24 (that is, the curved portions 24p) across the bridge points. The electric resistance of the outer-peripheral sub resistance heating elements 25 can be adjusted by the material of the outer-peripheral sub resistance heating element 25, the size of a sectional area, or the lengths of the bridge points. The outer-peripheral sub resistance heating elements 25 form parallel circuits together with the outer-peripheral main resistance heating element 24. The outer-peripheral sub resistance heating elements 25 can be formed by applying high-melting-point metal or the paste of carbide thereof by printing. The frame at the lower right in FIG. 3 contains an enlarged view of a portion around one of the gas holes 26. However, the outer-peripheral sub resistance heating elements 25 are formed around the other gas holes 26 in the same manner. In the case where a problem arises from a decrease in the amount of heat generation of each curved portion 24p as a result of the curved portion 24p and the outer-peripheral sub resistance heating elements 25 being arranged in parallel, the problem can be solved by decreasing the coil winding pitch of the curved portion 24p to be less than the coil winding pitch outside the curved portion 24p such that the amount of heat generation of the curved portion 24p increases.

The tubular shaft 40 is composed of ceramics such as aluminum nitride or alumina as in the ceramic plate 20. The inner diameter of the tubular shaft 40 is, for example, about 40 mm, and the outer diameter thereof is, for example, about 60 mm. The upper end of the tubular shaft 40 is diffusion-joined to the ceramic plate 20. Power supply rods 42a and 42b that are connected to the respective a pair of main terminals 22a and 22b of the inner-peripheral main resistance heating element 22 and power supply rods 44a and 44b that are connected to the respective a pair of terminals 24a and 24b of the outer-peripheral main resistance heating element 24 are disposed in the tubular shaft 40. The power supply rods 42a and 42b are connected to a first power supply 32, and the power supply rods 44a and 44b are connected to a second power supply 34. This achieves separate temperature control of the inner-peripheral zone Z1 that is heated by the inner-peripheral main resistance heating element 22 and the inner-peripheral sub resistance heating elements 23 connected thereto in parallel and the outer-peripheral zone Z2 that is heated by the outer-peripheral main resistance heating element 24 and the outer-peripheral sub resistance heating elements 25 connected thereto in parallel. Gas supply pipes through which gas is supplied to the gas holes 26 and the lift pins that are inserted in the lift pin holes 28 are also disposed in the tubular shaft 40 although these are not illustrated.

An example of the use of the ceramic heater 10 will now be described. The ceramic heater 10 is first installed in the vacuum chamber not illustrated, and the wafer W is placed on the wafer placement surface 20a of the ceramic heater 10. The first power supply 32 adjusts power that is supplied to the inner-peripheral main resistance heating element 22 and the inner-peripheral sub resistance heating elements 23 such that the temperature of the inner-peripheral zone Z1 that is detected by an inner-peripheral thermocouple not illustrated becomes a predetermined inner-peripheral target temperature. In addition to this, the second power supply 34 adjusts power that is supplied to the outer-peripheral main resistance heating element 24 and the outer-peripheral sub resistance heating elements 25 such that the temperature of the outer-peripheral zone Z2 that is detected by an outer-peripheral thermocouple not illustrated becomes a predetermined outer-peripheral target temperature. Consequently, the temperature of the wafer W is controlled so as to be the desired temperature. Settings are adjusted such that the interior of the vacuum chamber becomes a vacuum atmosphere or a decompression atmosphere, plasma is produced in the vacuum chamber, a CVD film is formed on the wafer W by using the plasma, and etching is performed.

As for the ceramic heater 10 according to the present embodiment described above, the sub resistance heating elements 23 and 25 have a ribbon shape and can be accordingly manufactured by printing, a line width and a line distance can be decreased, and the degree of freedom of wiring can be increased. For this reason, the sub resistance heating elements 23 and 25 can complement heating with the main resistance heating elements 22 and 24 that have a coil shape. Accordingly, sufficient thermal uniformity can be achieved even in the case where the coils are used as the main resistance heating elements 22 and 24.

The main resistance heating elements 22 and 24 are the coils and are accordingly restricted when wired. For example, the main resistance heating elements 22 and 24 need to be wired so as to detour around the gas holes 26 and the lift pin holes 28. For this reason, portions around the holes 26 and 28 are likely to have the temperature singularity. Since the sub resistance heating elements 23 and 25 are disposed around the holes 26 and 28 here, the portions around the holes 26 and 28 can be prevented from having the temperature singularity.

The inner-peripheral sub resistance heating elements 23 form the parallel circuits together with the inner-peripheral main resistance heating element 22, and the outer-peripheral sub resistance heating elements 25 form the parallel circuits together with the outer-peripheral main resistance heating element 24. For this reason, it is not necessary for the sub resistance heating elements 23 and 25 to include exclusive terminals.

It should be noted that the present invention is not limited to the above-described embodiment at all, and it is needless to say that the present invention can be implemented in various embodiments without departing from the technical scope of the present invention.

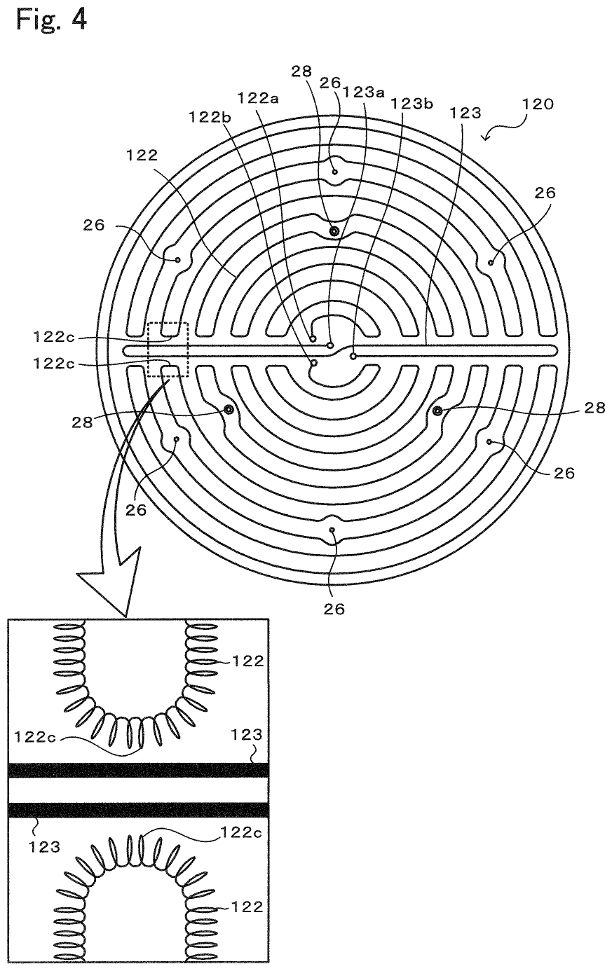

For example, a ceramic plate 120 illustrated in FIG. 4 may be used instead of the ceramic plate 20 according to the embodiment described above. FIG. 4 is a sectional view of the ceramic plate 120 taken along a plane parallel with resistance heating elements 122 and 123 and viewed from above (hatching representing a section is omitted). In the ceramic plate 120, the main resistance heating element 122 and the sub resistance heating element 123 are embedded. The main resistance heating element 122 extends from one of a pair of main terminals 122a and 122b, is folded at multiple folded portions 122c in a one-stroke pattern, is wired over the substantially entire wafer placement surface, and reaches the other of the pair of the main terminals 122a and 122b. The main resistance heating element 122 is disposed so as to detour around the lift pin holes 28 and the gas holes 26. The main resistance heating element 122 is a coil a main component of which is high-melting-point metal or carbide thereof. The sub resistance heating element 123 extends from one of a pair of sub terminals 123a and 123b disposed on the central portion, is wired so as to pass through a portion at which the folded portions 122c of the main resistance heating element 122 face each other, and reaches the other of the pair of the sub terminals 123a and 123b. The sub resistance heating element 123 is a ribbon a main component of which is high-melting-point metal or carbide thereof and is formed by applying paste by printing.

In FIG. 4, the main resistance heating element 122 is the coil, and accordingly, the portion at which the folded portions 122c face each other is relatively wide and is likely to have the temperature singularity. In some cases where the ceramic heater 10 is manufactured, the coil is embedded in ceramics powder and is subsequently fired. In these cases, the coil moves in the ceramics powder. In consideration for this, the distance between the folded portions 122c is set to be relatively long. The sub resistance heating element 123 that is the ribbon is formed by printing at the portion at which the folded portions 122c face each other here. A space between the folded portions 122c typically needs to be about 1 mm in length. In contrast, a space between parts of the ribbon can be about 0.3 mm in length because the ribbon can be manufactured by printing. For this reason, the sub resistance heating element 123 can be disposed at the portion at which the folded portions 122c face each other, and the portion can be prevented from having the temperature singularity. Heating with the main resistance heating element 122 and heating with the sub resistance heating element 123 can be separately controlled in a manner in which the pair of the main terminals 122a and 122b of the main resistance heating element 122 is connected to the first power supply, and the pair of the sub terminals 123a and 123b of the sub resistance heating element 123 is connected to the second power supply that differs from the first power supply.

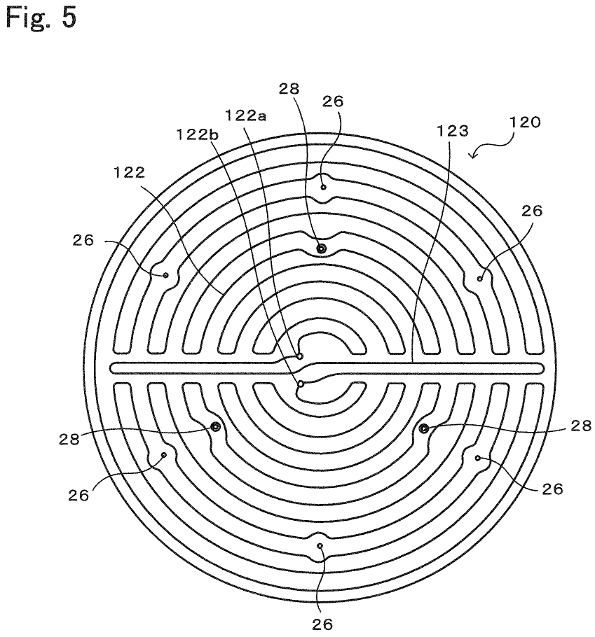

As for the ceramic plate 120, as illustrated in FIG. 5, the sub resistance heating element 123 may extend from one of the pair of the main terminals 122a and 122b and reach the other. That is, the sub resistance heating element 123 may form a parallel circuit together with the main resistance heating element 122. In this case, it is not necessary for the sub resistance heating element 123 to include an exclusive terminal.

In FIG. 4 and FIG. 5, the sub resistance heating elements 23 and 25 may be disposed around the lift pin holes 28 and around the gas holes 26 as in the embodiment described above.

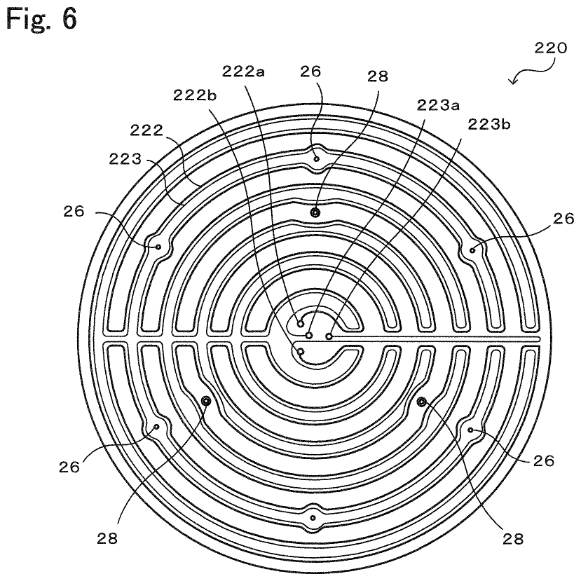

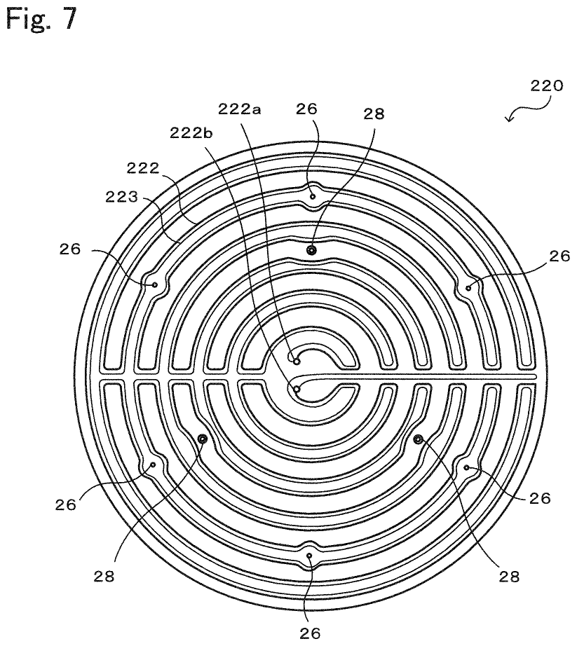

The sub resistance heating elements 23 and 25 according to the embodiment described above, the sub resistance heating element 123 in FIG. 4 and FIG. 5, and a sub resistance heating element 223 in the FIG. 6 and FIG. 7 may contain ceramics. For example, when the sub resistance heating elements 23, 25, 123, and 223 are formed by printing, paste may contain ceramics. In this way, the thermal expansion coefficients of the sub resistance heating elements 23, 25, 123, and 223 can be close to the thermal expansion coefficient of the ceramic plate 20, and bonding strength between the sub resistance heating elements 23, 25, 123, and 223 and the ceramic plate 20 can be increased.

A ceramic plate 220 illustrated in FIG. 6 may be used instead of the ceramic plate 20 according to the embodiment described above. FIG. 6 is a sectional view of the ceramic plate 220 taken along a plane parallel with a resistance heating element 222 and the resistance heating element 223 and viewed from above (hatching representing a section is omitted). In the ceramic plate 220, the main resistance heating element 222 and the sub resistance heating element 223 are embedded. The main resistance heating element 222 extends from one of a pair of main terminals 222a and 222b, is folded at folded portions in a one-stroke pattern, is wired over the substantially entire wafer placement surface, and reaches the other of the pair of the main terminals 222a and 222b. The main resistance heating element 222 is disposed so as to detour around the lift pin holes 28 and the gas holes 26. The main resistance heating element 222 is a coil a main component of which is high-melting-point metal or carbide thereof. The sub resistance heating element 223 extends from one of a pair of sub terminals 223a and 223b, is wired along the main resistance heating element 222, and reaches the other of the pair of the sub terminals 223a and 223b. The sub resistance heating element 223 is a ribbon a main component of which is high-melting-point metal or carbide thereof and is formed by applying paste by printing.

In FIG. 6, the main resistance heating element 222 is the coil. Accordingly, a space between parts of the coil is relatively wide and is likely to have the temperature singularity. The sub resistance heating element 223 that is the ribbon is formed by printing in the space between the parts of the coil. The space between the parts of the coil is typically about 1 mm in length. In contrast, a space between parts of the ribbon can be about 0.3 mm in length because the ribbon can be manufactured by printing. For this reason, the sub resistance heating element 223 can be disposed in the space between the parts of the coil, and this portion can be prevented from having the temperature singularity. Heating with the main resistance heating element 222 and heating with the sub resistance heating element 223 can be separately controlled in a manner in which the pair of the main terminals 222a and 222b of the main resistance heating element 222 is connected to the first power supply, and the pair of the sub terminals 223a and 223b of the sub resistance heating element 223 is connected to the second power supply that differs from the first power supply.

As for the ceramic plate 220, as illustrated in FIG. 7, the sub resistance heating element 223 may extend from one of the pair of the main terminals 222a and 222b and may reach the other. That is, the sub resistance heating element 223 may form a parallel circuit together with the main resistance heating element 222. In this case, it is not necessary for the sub resistance heating element 223 to include an exclusive terminal.

According to the embodiment described above, the sub resistance heating elements 23 and 25 are the ribbons but are not particularly limited thereto, and any shape may be used provided that the shape is a two-dimensional shape. The two-dimensional shape enables manufacturing to be performed by applying paste by printing. Accordingly, the sub resistance heating elements 23 and 25 can be readily thinned and can be wired at a high density.

According to the embodiment described above, the ceramic plate 20 may contain an electrostatic electrode. In this case, the wafer W can be electrostatically sucked and held on the wafer placement surface 20a by applying a voltage to the electrostatic electrode after the wafer W is placed on the wafer placement surface 20a. The ceramic plate 20 may contain a RF electrode. In this case, a shower head, not illustrated, is disposed with a space created above the wafer placement surface 20a, and high-frequency power is supplied between parallel flat plate electrodes including the shower head and the RF electrode. In this way, plasma is produced, a CVD film can be formed on the wafer W by using the plasma, and etching can be performed. The electrostatic electrode may double as the RF electrode. The same is true for the ceramic plates 120 and 220 in FIG. 4 to FIG. 7.

According to the embodiment described above, the outer-peripheral zone Z2 is described as a single zone but may be divided into multiple small zones. In this case, the resistance heating elements are separately wired for every small zone. Each small zone may be formed into an annular shape by dividing the outer-peripheral zone Z2 by a boundary line concentric with the ceramic plate 20 or may be formed into a sectorial shape (a shape obtained by unfolding the side surface of a truncated cone) by dividing the outer-peripheral zone Z2 by lines radially extending from the center of the ceramic plate 20.

According to the embodiment described above, the inner-peripheral zone Z1 is described as a single zone but may be divided into multiple small zones. In this case, the resistance heating elements are separately wired for every small zone. Each small zone may be formed into an annular shape and a circular shape by dividing the inner-peripheral zone Z1 by a boundary line concentric with the ceramic plate 20 or may be formed into a sectorial shape (a shape obtained by unfolding the side surface of a cone) by dividing the inner-peripheral zone Z1 by lines radially extending from the center of the ceramic plate 20.

This application claims the priority of Japanese Patent Application No. 2019-011300, filed on Jan. 25, 2019, the entire contents of which are incorporated herein by reference in their entirety.

What is claimed is:

1. A ceramic heater comprising:
a ceramic plate that has a wafer placement surface;
a main resistance heating element that is disposed parallel with the wafer placement surface in the ceramic plate, that is wired from one of a pair of main terminals in a one-stroke pattern, that reaches the other of the pair of main terminals, and that has a coil shape; and
a sub resistance heating element that is disposed in the ceramic plate, that complements heating with the main resistance heating element, and that has a two-dimensional shape.

2. The ceramic heater according to claim 1,
wherein the ceramic plate has a hole that extends therethrough in a vertical direction, and
wherein the sub resistance heating element is disposed around the hole.

3. The ceramic heater according to claim 1,
wherein the main resistance heating element extends from the one of the pair of main terminals, is folded at folded portions, and reaches the other of the pair of main terminals, and
wherein the sub resistance heating element is disposed at a portion at which the folded portions of the main resistance heating element face each other.

4. The ceramic heater according to claim 1,
wherein the sub resistance heating element is disposed in a space between parts of a wiring line of the main resistance heating element.

5. The ceramic heater according to claim 1,
wherein the sub resistance heating element forms a parallel circuit together with the main resistance heating element.

6. The ceramic heater according to claim 1,
wherein the sub resistance heating element is wired from one of a pair of sub terminals in a one-stroke pattern and reaches the other of the pair of sub terminals.

7. The ceramic heater according to claim 1,
wherein the sub resistance heating element contains ceramics.

8. The ceramic heater according to claim 1,
wherein the sub resistance heating element is disposed so as to bridge a curved portion of the main resistance heating element, and
wherein a coil winding pitch of the curved portion is less than a coil winding pitch outside the curved portion.
